(19) United States
(12) Patent Application Publication
(10) Pub. No.: US 2026/0190470 A1
(43) Pub. Date: Jul. 2, 2026

(54) SOURCE/DRAIN REGIONS IN STACKING TRANSISTORS AND METHODS OF FORMING THE SAME

(71) Applicant: Taiwan Semiconductor Manufacturing Co., Ltd., Hsinchu (TW)

(72) Inventors: Hung-Kun Lo, New Taipei (TW); Ku-Feng Yang, Baoshan Township (TW); Che Chi Shih, Taoyuan (TW); Yu-Hsien Chiang, Hsinchu (TW); Szuya Liao, Zhubei (TW)

(21) Appl. No.: 19/215,058

(22) Filed: May 21, 2025

Related U.S. Application Data
(60) Provisional application No. 63/741,302, filed on Jan. 2, 2025.

(51) Int. Cl. H10D 84/85; H01L 21/02; H01L 21/3105; H01L 21/311; H10D 30/00; H10D 30/01; H10D 62/10; H10D 64/23; H10D 84/01

(52) U.S. Cl. CPC H10D 84/851; H10D 30/019; H10D 30/502; H10D 62/121; H10D 64/254; H10D 64/256; H10D 84/0186; H10D 84/856; H10P 14/6682; H10P 14/6687; H10P 50/287; H10P 95/08

(57) ABSTRACT

In an embodiment, a method includes forming an upper gate structure adjacent to a first source/drain region and a second source/drain region and a lower gate structure adjacent to a third source/drain region; patterning a first opening and a second opening through a first dielectric layer to expose the first source/drain region and the second source/drain region; patterning to extend the second opening through a second dielectric layer to expose the third source/drain region; forming a protective layer over exposed surfaces of the first dielectric layer; forming a first epitaxial regrowth layer over the first source/drain region and a second epitaxial regrowth layer over the second source/drain region; removing the protective layer; forming a first source/drain contact to the first epitaxial regrowth layer; and forming a second source/drain contact to the second epitaxial regrowth layer and the third source/drain region.

### PRIORITY CLAIM AND CROSS-REFERENCE

This application claims the benefit of the following provisionally filed U.S. Patent application: Application No. 63/741,302, filed on Jan. 2, 2025, and entitled “METHOD OF MANUFACTURING SEMICONDUCTOR STRUCTURE THEREOF,” which application is hereby incorporated herein by reference.

### BACKGROUND

Semiconductor devices are used in a variety of electronic applications such as personal computers, cell phones, digital cameras, and other electronic equipment. Semiconductor devices are typically fabricated by sequentially depositing insulating or dielectric layers, conductive layers, and semiconductor layers over a semiconductor substrate, and patterning the various material layers using lithography to form circuit components and elements thereon.

The semiconductor industry continues to improve the integration density of various electronic components (e.g., transistors, diodes, resistors, capacitors, etc.) by continual reductions in minimum feature size, which allow more components to be integrated into a given area. As the semiconductor industry further progresses towards increased device density, higher performance, and lower costs, challenges from both fabrication and design have led to stacked device configurations, such as stacking transistors, which include complementary field effect transistors (CFETs). As the minimum feature sizes are reduced, however, additional features are introduced.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 illustrates a perspective view of an example stacking transistor, in accordance with some embodiments.

FIGS. 2, 3, 4, 4, 5, 6, 7, 8, 9, 10, 11, 12, and 13 are views of intermediate stages in the manufacturing of stacking transistors, in accordance with some embodiments.

FIGS. 14, 15, and 16 are views of intermediate stages in the manufacturing of stacking transistors, in accordance with some additional embodiments.

FIGS. 17 and 18 illustrate chemical structures and reaction mechanisms of intermediate stages in the manufacturing of stacking transistors, in accordance with some embodiments.

FIGS. 19, 20, and 21 illustrate process flows of intermediate stages in the manufacturing of stacking transistors, in accordance with some embodiments.

### DETAILED DESCRIPTION

The following disclosure provides many different embodiments, or examples, for implementing different features of the invention. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “underlying,” “below,” “lower,” “overlying,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

A stacking transistor structure and the method of forming the same are provided. Stacking transistor structures, such as complementary field effect transistors (CFETs), and methods of forming the same are provided. The stacking transistor structure includes two transistors that are vertically stacked and that are of opposite types (e.g., an n-type transistor and a p-type transistor that are vertically stacked). As such, source/drain regions of vertically stacked transistors may also be vertically stacked. In addition, source/drain region contacts may be formed to the upper source/drain regions and/or the lower source/drain regions. Patterning steps may be used to form contact openings to the upper source/drain regions, and some of the contact openings may be extended to the lower source/drain regions. Formation of the contact openings to the lower source/drain regions may include etching through overlying upper source/drain regions. Embodiments herein include formation of one or more protective layers over the structure while the upper source/drain regions remain exposed. An epitaxial regrowth process may then be performed on the upper source/drain regions (e.g., the etched-through upper source/drain regions). For example, the protective layer may include a self-assembled monolayer (SAM) which selectively forms along certain dielectric surfaces while certain epitaxial surfaces remain exposed for subsequent epitaxial regrowth. After performing the epitaxial regrowth process, the protective layer is removed, and contact plugs are formed in the contact openings. The resulting upper source/drain regions will perform at a higher level and with greater reliability, which results in improved yield, performance, and reliability of the corresponding transistors.

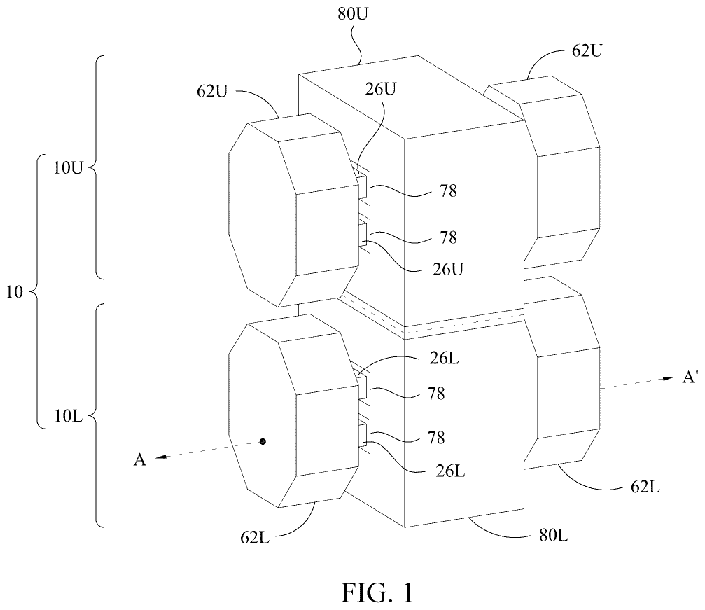

FIG. 1 illustrates an example of a stacking transistor 10 (including FETs (transistors) 10U and 10L) in accordance with some embodiments. FIG. 1 is a three-dimensional view, and some features of the stacking transistor are omitted for illustration clarity.

The stacking transistor includes multiple vertically stacked FETs. For example, a stacking transistor may include a lower nanostructure-FET 10L of a first device type (e.g., n-type/p-type) and an upper nanostructure-FET 10U of a second device type (e.g., p-type/n-type). When the stacking transistor is a CFET, the second device type of the upper nanostructure-FET 10U is opposite to the first device type of the lower nanostructure-FET 10L. The nanostructure-FETs 10U and 10L include semiconductor nanostructures 26 (including lower semiconductor nanostructures 26L and upper semiconductor nanostructures 26U), where the semiconductor nanostructures 26 act as the channel regions for the nanostructure-FETs. The lower semiconductor nanostructures 26L are for the lower nanostructure-FET 10L, and the upper semiconductor nanostructures 26U are for the upper nanostructure-FET 10U. In other embodiments, the stacking transistors may be applied to other types of transistors (e.g., finFETs, or the like) as well.

Gate dielectrics 78 encircle the respective semiconductor nanostructures 26. Gate electrodes 80 (including a lower gate electrode 80L and an upper gate electrode 80U) are over the gate dielectrics 78. Source/drain regions 62 (including lower source/drain regions 62L and upper source/drain regions 62U) are disposed on opposing sides of the gate dielectrics 78 and the respective gate electrodes 80. Each of the source/drain regions 62 may refer to a source or a drain, individually or collectively dependent upon the context. Isolation features (not shown) may be formed to separate desired ones of the source/drain regions 62 and/or desired ones of the gate electrodes 80. Note that the upper and the lower source/drain regions 62U, 62L may be referred to by the conductive types (e.g., p-type or n-type) of the corresponding nanostructure-FETs.

FIG. 1 further illustrates reference cross-sections that are used in later figures. Cross-section A-A′ is a vertical cross-section that is parallel to a longitudinal axis of the semiconductor nanostructures 26 of a stacking transistor and in a direction of, for example, a current flow between the source/drain regions 62 of the stacking transistor. Subsequent figures may refer to this reference cross-section for clarity.

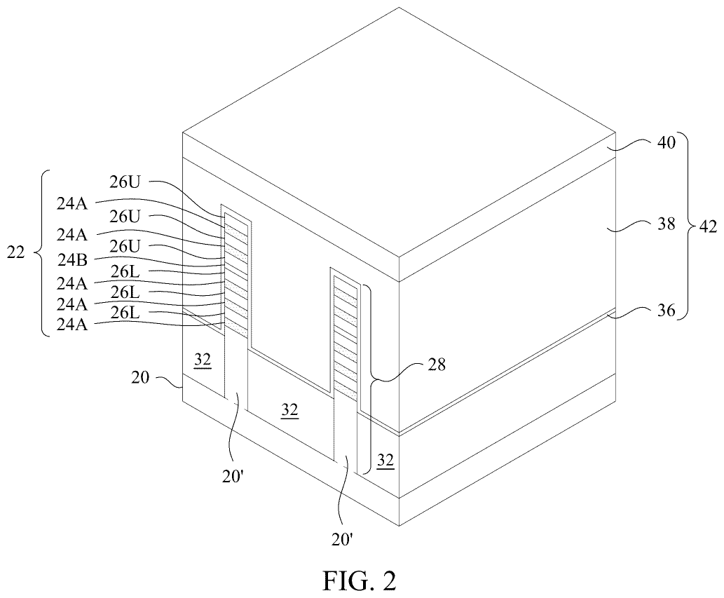

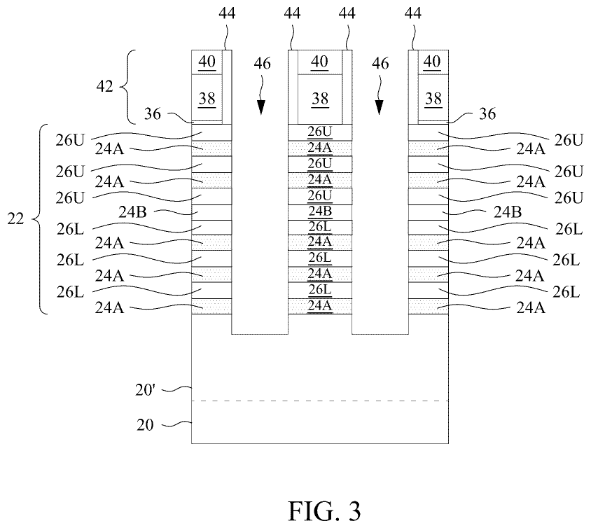

FIG. 2 illustrates a three-dimensional view and FIGS. 3 through 16 illustrate cross-sectional views of intermediate stages in the formation of various stacking transistors (as schematically represented in FIG. 1), in accordance with some embodiments. In subsequent discussion, unless specified otherwise, FIGS. 3 through 16 illustrate the vertical cross-sectional views along a similar cross-section as vertical reference cross-section A-A′ in FIG. 1.

In FIG. 2, a wafer, which includes substrate 20, is provided. Substrate 20 may be a semiconductor substrate, such as a bulk semiconductor, which may be doped (e.g., with a p-type or an n-type dopant) or undoped. Other substrates, such as a multi-layered or gradient substrate may also be used. In some embodiments, the semiconductor material of the substrate 20 may include silicon, germanium, carbon-doped silicon, a III-V compound semiconductor; or the like, or combinations thereof.

Semiconductor strips 28 are formed extending upwards from the semiconductor substrate 20. Each of semiconductor strips 28 includes semiconductor strip 20′ (patterned portions of the semiconductor substrate 20, also referred to as semiconductor fins 20′) and a multi-layer stack 22. The stacked components of the multi-layer stack 22 are referred to as nanostructures hereinafter. Specifically, the multi-layer stack 22 includes dummy nanostructures 24A, one or more dummy nanostructures 24B, lower semiconductor nanostructures 26L, and upper semiconductor nanostructures 26U. The dummy nanostructures 24A and the dummy nanostructures 24B may further be collectively referred to as dummy nanostructures 24, and the lower semiconductor nanostructures 26L and the upper semiconductor nanostructures 26U may further be collectively referred to as semiconductor nanostructures 26.

The dummy nanostructures 24A are formed of a first semiconductor material, and the dummy nanostructures 24B are formed of a second semiconductor material different from the first semiconductor material. The first and second semiconductor materials may be selected from the candidate semiconductor materials of the substrate 20. The first and second semiconductor materials have a high etching selectivity to one another. As such, the dummy semiconductor layer 24B may be removed at a faster rate than the dummy semiconductor layers 24A in subsequent processes.

The semiconductor nanostructures 26 (including the lower semiconductor nanostructures 26L and upper semiconductor nanostructures 26U) are formed of one or more third semiconductor material(s). The third semiconductor material(s) may be selected from the candidate semiconductor materials of the substrate 20. The lower semiconductor nanostructures 26L and the upper semiconductor nanostructures 26U may be formed of the same semiconductor material, or may be formed of different semiconductor materials. Further, the first and second semiconductor materials of the dummy nanostructures 24 have a high etching selectivity to the third semiconductor material(s) of the semiconductor nanostructures 26. As such, the dummy nanostructures 24 may be selectively removed in subsequent process steps without significantly removing the semiconductor nanostructures 26. In some embodiments, the dummy nanostructures 24A are formed of or comprise silicon germanium, the semiconductor nanostructures 26 are formed of silicon, and the dummy nanostructures 24B may be formed of germanium or silicon germanium with a higher germanium atomic percentage than the dummy nanostructures 24A.

The lower semiconductor nanostructures 26L will provide channel regions for lower nanostructure-FETs of the CFETs. The upper semiconductor nanostructures 26U will provide channel regions for upper nanostructure-FETs of the CFETs. The semiconductor nanostructures 26 that are immediately above/below (e.g., in contact with) the dummy nanostructures 24B may be used for isolation and may or may not act as channel regions for the CFETs. The dummy nanostructures 24B will be subsequently replaced with isolation structures that define boundaries of the lower nanostructure-FETs and the upper nanostructure-FETs.

To form the semiconductor strips 28, layers of the first, second, and third semiconductor materials (arranged as illustrated and described above) may be deposited over the semiconductor substrate 20. The layers of the first, second, and third semiconductor materials may be grown by a process such as Vapor Phase Epitaxy (VPE) or Molecular Beam Epitaxy (MBE), deposited by a process such as Chemical Vapor Deposition (CVD) process or an Atomic Layer deposition (ALD) process, or the like. Then, a patterning process may be applied to the layers of the first, second, and third semiconductor materials as well as the semiconductor substrate 20 to define the semiconductor strips 28, which includes the semiconductor strips 20′, the dummy nanostructures 24, and the semiconductor nanostructures 26.

The semiconductor fins and the nanostructures may be patterned by any suitable method. For example, the patterning process may include one or more photolithography processes, including double-patterning or multi-patterning processes. Generally, double-patterning or multi-patterning processes combine photolithography and self-aligned processes, allowing patterns to be created that have, for example, pitches smaller than what is otherwise obtainable using a single, direct photolithography process. For example, in one embodiment, a sacrificial layer is formed over a substrate and patterned using a photolithography process. Spacers are formed alongside the patterned sacrificial layer using a self-aligned process. The sacrificial layer is then removed, and the remaining spacers may then be used as an etching mask for the patterning process to etch the layers of the first, second, and third semiconductor materials and the semiconductor substrate 20. The etching may be performed by any acceptable etch process, such as a Reactive Ion Etch (RIE), Neutral Beam Etch (NBE), the like, or a combination thereof. The etching may be anisotropic.

As also illustrated by FIG. 2, isolation regions 32 such as shallow trench isolation (STI) regions 32 are formed over the substrate 20 and between adjacent semiconductor strips 28. STI regions 32 may include a dielectric liner and a dielectric material over the dielectric liner. Each of the dielectric liner and the dielectric material may include an oxide such as silicon oxide, a nitride, such as silicon nitride, the like, or a combination thereof. The formation of the STI regions 32 may include depositing the dielectric layer(s), and performing a planarization process such as a Chemical Mechanical Polish (CMP) process, a mechanical polishing process, or the like to remove excess portions of the dielectric materials. The deposition processes may include ALD, High-Density Plasma CVD (HDP-CVD), Flowable CVD (FCVD), the like, or a combination thereof. In some embodiments, the STI regions 32 include silicon oxide formed by an FCVD process, followed by an anneal process. Then, the dielectric layers(s) are recessed to define the STI regions 32. The dielectric layer(s) may be recessed such that upper portions of semiconductor strips 28 (including multi-layer stacks 22) protrude higher than the remaining STI regions 32.

After the STI regions 32 are formed, dummy gate stacks 42 may be formed over and along sidewalls of the upper portions of the semiconductor strips 28 (the portions that protrude higher than the STI regions 32). Forming the dummy gate stacks 42 may include forming dummy dielectric layer 36 on the semiconductor strips 28. The dummy dielectric layer 36 may be formed of or comprise, for example, silicon oxide, silicon nitride, a combination thereof, or the like, and may be deposited or thermally grown according to acceptable techniques. A dummy gate layer 38 is formed over the dummy dielectric layer 36. The dummy gate layer 38 may be deposited, for example, through Physical Vapor Deposition (PVD), CVD, or other techniques, and then planarized, such as by a CMP process. The material of dummy gate layer 38 may be conductive or non-conductive, and may be selected from a group including amorphous silicon, polycrystalline-silicon (polysilicon), poly-crystalline silicon-germanium (poly-SiGe), or the like. A mask layer 40 is formed over the planarized dummy gate layer 38, and may include, for example, silicon nitride, silicon oxynitride, or the like. Next, the mask layer 40 may be patterned through photolithography and etching processes to form a mask, which is then used to etch and pattern dummy gate layer 38, and possibly the dummy dielectric layer 36. The remaining portions of mask layer 40, dummy gate layer 38, and dummy dielectric layer 36 form dummy gate stacks 42.

In FIG. 3, gate spacers 44 and source/drain recesses 46 are formed. First, the gate spacers 44 are formed over the multi-layer stacks 22 and on exposed sidewalls of dummy gate stacks 42. The gate spacers 44 may be formed by conformally forming one or more dielectric layers and subsequently etching the dielectric layers anisotropically. The applicable dielectric materials may include silicon oxide, silicon nitride, silicon oxynitride, silicon oxycarbonitride, or the like, which may be formed by a deposition process such as CVD, ALD, or the like. Fin spacers (not specifically illustrated) may also be formed as part of forming the gate spacers 44.

Subsequently, source/drain recesses 46 are formed in semiconductor strips 28. The source/drain recesses 46 are formed through etching, and may extend through the multi-layer stacks 22 and into the semiconductor strips 20′. Bottom surfaces of the source/drain recesses 46 may be at a level above, below, or level with the top surfaces of the isolation regions 32. In the etching processes, the gate spacers 44 and the dummy gate stacks 42 mask some portions of the semiconductor strips 28. The etching may include a single etch process or multiple etch processes. Timed etch processes may be used to stop the etching of the source/drain recesses 46 upon the source/drain recesses 46 reaching a desired depth.

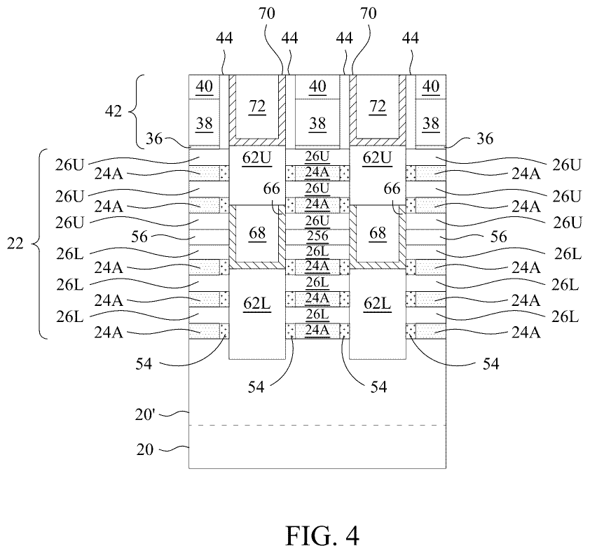

FIG. 4 illustrates various subsequent processing steps. In particular, inner spacers 54 and dielectric isolation layers 56 are formed. Forming the inner spacers 54 and the dielectric isolation layers 56 may include an etching process that laterally etches the dummy nanostructures 24A and removes the dummy nanostructures 24B. The etching process may be isotropic and may be selective to the material of the dummy nanostructures 24, so that the dummy nanostructures 24 are etched at a faster rate than the semiconductor nanostructures 26. The etching process may also be selective to the material of the dummy nanostructures 24B, so that the dummy nanostructures 24B are etched at a faster rate than the dummy nanostructures 24A. In this manner, the dummy nanostructures 24B may be completely removed from between the lower semiconductor nanostructures 26L (collectively) and the upper semiconductor nanostructures 26U (collectively) without completely removing the dummy nanostructures 24A.

In some embodiments where the dummy nanostructures 24B are formed of germanium or silicon germanium with a high germanium atomic percentage, the dummy nanostructures 24A are formed of silicon germanium with a low germanium atomic percentage, and the semiconductor nanostructures 26 are formed of silicon free from germanium, the etch process may comprise a dry etch process using chlorine gas, with or without a plasma. Because the dummy gate stacks 42 wrap around sidewalls of the semiconductor nanostructures 26 (see FIG. 2), the dummy gate stacks 42 may support the upper semiconductor nanostructures 26U so that the upper semiconductor nanostructures 26U do not collapse upon removal of the dummy nanostructures 24B. Further, although sidewalls of the dummy nanostructures 24A are illustrated as being straight after the etching, the sidewalls may be concave or convex.

The inner spacers 54 are formed on sidewalls of the recessed dummy nanostructures 24A, and dielectric isolation layers 56 are formed between the upper semiconductor nanostructures 26U (collectively) and the lower semiconductor nanostructures 26L (collectively). As subsequently described in greater detail, source/drain regions will be subsequently formed in the source/drain recesses 46, and the dummy nanostructures 24A will be replaced with corresponding gate structures. The inner spacers 54 act as isolation features between the subsequently formed source/drain regions and the subsequently formed gate structures. Further, the inner spacers 54 may be used to prevent damage to the subsequently formed source/drain regions by subsequent etch processes, such as the etch processes used to form gate structures. The dielectric isolation layers 56, on the other hand, are used to isolate the upper semiconductor nanostructures 26U (collectively) from the lower semiconductor nanostructures 26L (collectively). Further, middle semiconductor nanostructures (ones of the semiconductor nanostructures 26 in contact with the dielectric isolation layers 56) and the dielectric isolation layers 56 may define the boundaries of the lower nanostructure-FETs and the upper nanostructure-FETs.

The inner spacers 54 and the dielectric isolation layers 56 may be formed by conformally depositing an insulating material in the source/drain recesses 46, on sidewalls of the dummy nanostructures 24, and between the upper and lower semiconductor nanostructures 26U and 26L, and then etching the insulating material. The insulating material may be a hard dielectric material, such as a carbon-containing dielectric material, such as silicon oxycarbonitride, silicon oxycarbide, silicon oxynitride, or the like. Other low-dielectric constant (low-k) materials having a k-value less than about 3.5 may be utilized. The insulating material may be formed by a deposition process, such as ALD, CVD, or the like. The etching of the insulating material may be anisotropic or isotropic. The insulating material, when etched, has portions remaining in the sidewalls of the dummy nanostructures 26A (thus forming the inner spacers 54) and has portions remaining in between the upper and lower semiconductor nanostructures 26U and 26L (thus forming the dielectric isolation layers 56).

As further illustrated by FIG. 4, lower and upper epitaxial source/drain regions 62L and 62U are formed. The lower epitaxial source/drain regions 62L are formed in the lower portions of the source/drain recesses 46. The lower epitaxial source/drain regions 62L are in contact with the lower semiconductor nanostructures 26L and are not in contact with the upper semiconductor nanostructures 26U. The inner spacers 54 electrically insulate the lower epitaxial source/drain regions 62L from the dummy nanostructures 24A, which will be replaced with replacement gates in subsequent processes.

The lower epitaxial source/drain regions 62L are epitaxially grown, and have a conductivity type that is suitable for the device type (p-type or n-type) of the lower nanostructure-FETs. When lower epitaxial source/drain regions 62L are n-type source/drain regions, the respective material may include silicon or carbon-doped silicon, which is doped with an n-type dopant such as phosphorous, arsenic, or the like. When lower epitaxial source/drain regions 62L are p-type source/drain regions, the respective material may include silicon or silicon germanium, which is doped with a p-type dopant such as boron, indium, or the like. The lower epitaxial source/drain regions 62L may be in-situ doped, and may be, or may not be, implanted with the corresponding p-type or n-type dopants. During the epitaxy of the lower epitaxial source/drain regions 62L, exposed surfaces of the upper semiconductor nanostructures 26U (e.g., sidewalls) may be masked to prevent undesired epitaxial growth on the upper semiconductor nanostructures 26U. After the lower epitaxial source/drain regions 62L are grown, the masks on the upper semiconductor nanostructures 26U may then be removed.

As a result of the epitaxy processes used for forming the lower epitaxial source/drain regions 62L, upper surfaces of the lower epitaxial source/drain regions 62L have facets which expand laterally outward beyond sidewalls of the multi-layer stacks 22. In some embodiments, adjacent lower epitaxial source/drain regions 62L remain separated after the epitaxy process is completed. In other embodiments, these facets cause neighboring lower epitaxial source/drain regions 62L of a same FET to merge.

A first contact etch stop layer (CESL) 66 and a first ILD 68 are formed over the lower epitaxial source/drain regions 62L. The first CESL 66 may be formed of a dielectric material having a high etching selectivity from the etching of the first ILD 68, such as silicon nitride, silicon oxide, silicon oxynitride, or the like, which may be formed by any suitable deposition process, such as CVD, ALD, or the like. The first ILD 68 may be formed of a dielectric material, which may be deposited by any suitable method, such as CVD, plasma-enhanced CVD (PECVD), or FCVD. The applicable dielectric material of the first ILD 68 may include phospho-silicate glass (PSG), boro-silicate glass (BSG), boron-doped phospho-silicate glass (BPSG), undoped silicate glass (USG), silicon oxide, or the like.

The formation processes may include depositing a conformal CESL layer, depositing a material for the first ILD 68, followed by a planarization process and then an etch-back process. In some embodiments, the first ILD 68 is etched first, leaving the first CESL 66 unetched. An anisotropic etching process is then performed to remove the portions of the first CESL 66 higher than the recessed first ILD 68. After the recessing, the sidewalls of the upper semiconductor nanostructures 26U are exposed.

Upper epitaxial source/drain regions 62U are then formed in the upper portions of the source/drain recesses 46. The upper epitaxial source/drain regions 62U may be epitaxially grown from exposed surfaces of the upper semiconductor nanostructures 26U. The materials of upper epitaxial source/drain regions 62U may be selected from the same candidate group of materials for forming lower source/drain regions 62L, depending on the desired conductivity type of upper epitaxial source/drain regions 62U. The conductivity type of the upper epitaxial source/drain regions 62U may be opposite the conductivity type of the lower epitaxial source/drain regions 62L in embodiments where the stacking transistors are CFETs. For example, the upper epitaxial source/drain regions 62U may be oppositely doped from the lower epitaxial source/drain regions 62L. Alternatively, the conductivity types of the upper epitaxial source/drain regions 62U and the lower epitaxial source/drain regions 62L may be the same. The upper epitaxial source/drain regions 62U may be in-situ doped, and/or may be implanted, with an n-type or p-type dopant. Adjacent upper source/drain regions 62U may remain separated after the epitaxy process or may be merged.

After the epitaxial source/drain regions 62U are formed, a second CESL 70 and a second ILD 72 are formed. The materials and the formation methods may be similar to the materials and the formation methods of first CESL 66 and first ILD 68, respectively, and are not discussed in detail herein. The formation process may include depositing the layers for CESL 70 and ILD 72, and performing a planarization process to remove the excess portion of the corresponding layers. After the planarization process, top surfaces of the second ILD 72, the gate spacers 44, and the masks 40 (if present) or the dummy gates 38 are substantially coplanar (within process variations). Accordingly, the top surfaces of the masks 40 (if present) or the dummy gates 38 are exposed through the second ILD 124. In the illustrated embodiment, the masks 40 remain after the removal process. In other embodiments, the masks 40 are removed such that the top surfaces of the dummy gates 38 are exposed through the second ILD 72.

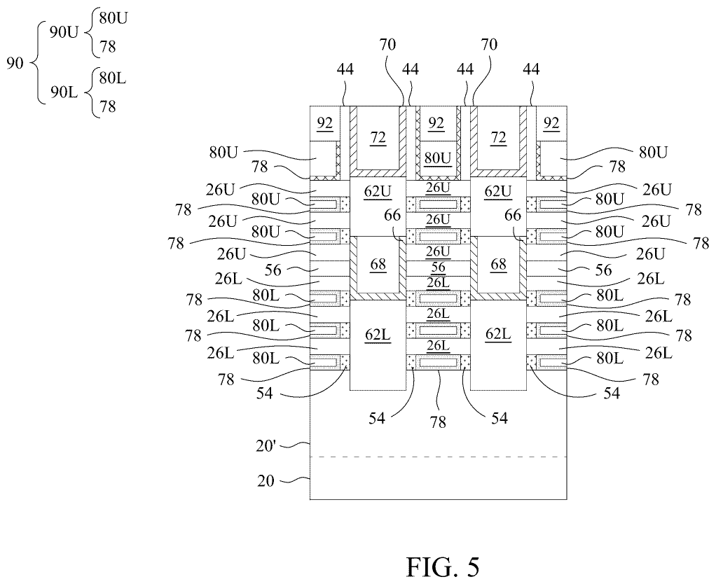

In FIG. 5, a replacement gate process is performed to replace the dummy gate stacks 42 and the dummy nanostructures 24A with gate stacks 90. The replacement gate process includes first removing the dummy gate stacks 42 and the remaining portions of the dummy nanostructures 24A. The dummy gate stacks 42 are removed in one or more etching processes, so that recesses are defined between the gate spacers 44 and the upper portions of the semiconductor strips 28 are exposed. The remaining portions of the dummy nanostructures 24A are then removed through etching, so that the recesses extend between the semiconductor nanostructures 26. In the etching process, the material of the dummy nanostructures 24A is etched at a faster rate than the materials of the semiconductor nanostructures 26, the dielectric isolation layers 56, and the inner spacers 54. The etching may be isotropic. For example, when the dummy nanostructures 24A are formed of silicon-germanium, and the semiconductor nanostructures 26 are formed of silicon, the etch process may include a wet etch process using tetramethylammonium hydroxide (TMAH), ammonium hydroxide (NH₄OH), or the like.

Then, gate dielectrics 78 are deposited in the recesses between the gate spacers 44 and on the exposed semiconductor nanostructures 26. The gate dielectrics 78 are conformally formed on the exposed surfaces of the recesses (the removed gate stacks 42 and the dummy nanostructures 24A) including the semiconductor nanostructures 26 and the gate spacers 44. In some embodiments, the gate dielectrics 78 wrap around all (e.g., four) sides of the semiconductor nanostructures 26. Specifically, the gate dielectrics 78 may be formed on the top surfaces of the fins 20′; on the top surfaces, the sidewalls, and the bottom surfaces of the semiconductor nanostructures 26; and on the sidewalls of the gate spacers 44. The gate dielectrics 78 may include an oxide such as silicon oxide or a metal oxide, a silicate such as a metal silicate, combinations thereof, multi-layers thereof, or the like. The gate dielectrics 78 may include a high-dielectric constant (high-k) material having a k-value greater than about 7.0, such as a metal oxide or a silicate of hafnium, aluminum, zirconium, lanthanum, manganese, barium, titanium, lead, and combinations thereof. The formation methods of the gate dielectrics 78 may include molecular-beam deposition (MBD), ALD, PECVD, and the like followed by a planarization process (e.g., a CMP) to remove portions of the gate dielectrics 78 above the second ILD 72. Although single-layered gate dielectrics 78 are illustrated, the gate dielectrics 78 may include multiple layers, such as an interfacial layer and an overlying high-k dielectric layer.

Lower gate electrodes 80L are formed on the gate dielectrics 78 around the lower semiconductor nanostructures 26L. For example, the lower gate electrodes 80L wrap around the lower semiconductor nanostructures 26L. The lower gate electrodes 80L may be formed of a metal-containing material such as tungsten, titanium, titanium nitride, tantalum, tantalum nitride, tantalum carbide, aluminum, ruthenium, cobalt, combinations thereof, multi-layers thereof, or the like. Although single-layered gate electrodes are illustrated, the lower gate electrodes 80L may include any number of work function tuning layers, any number of barrier layers, any number of glue layers, and a fill material.

The lower gate electrodes 80L are formed of material(s) that are suitable for the device type of the lower nanostructure-FETs. For example, the lower gate electrodes 80L may include one or more work function tuning layer(s) formed of material(s) that are suitable for the device type of the lower nanostructure-FETs. In some embodiments, the lower gate electrodes 80L include an n-type work function tuning layer, which may be formed of titanium aluminum, titanium aluminum carbide, tantalum aluminum, tantalum carbide, combinations thereof, or the like. In some embodiments, the lower gate electrodes 80L include a p-type work function tuning layer, which may be formed of titanium nitride, tantalum nitride, combinations thereof, or the like. Additionally or alternatively, the lower gate electrodes 80L may include a dipole-inducing element that is suitable for the device type of the lower nanostructure-FETs. Acceptable dipole-inducing elements include lanthanum, aluminum, scandium, ruthenium, zirconium, erbium, magnesium, strontium, and combinations thereof.

The lower gate electrodes 80L may be formed by conformally depositing one or more gate electrode layer(s) recessing the gate electrode layer(s). Any acceptable etch process, such as a dry etch, a wet etch, the like, or a combination thereof, may be performed to recess the gate electrode layer(s). The etching may be isotropic. Etching the lower gate electrodes 80L may expose the upper semiconductor nanostructures 26U.

In some embodiments, isolation layers (not explicitly illustrated) may be optionally formed on the lower gate electrodes 80L. The isolation layers act as isolation features between the lower gate electrodes 80L and subsequently formed upper gate electrodes 80U. The isolation layers may be formed by conformally depositing a dielectric material (e.g., silicon oxide, silicon nitride, silicon oxynitride, silicon oxycarbonitride, combinations thereof, or the like) and subsequently recessing the dielectric material to expose the upper semiconductor nanostructures 26U.

Then, upper gate electrodes 80U are formed on the isolation layers described above (if present) or the lower gate electrodes 80L. The upper gate electrodes 80U are disposed between the upper semiconductor nanostructures 26U. In some embodiments, the upper gate electrodes 80U wrap around the upper semiconductor nanostructures 26U. The upper gate electrodes 80U may be formed of the same candidate materials and candidate processes for forming the lower gate electrodes 80L. The upper gate electrodes 80U are formed of material(s) that are suitable for the device type of the upper nanostructure-FETs. For example, the upper gate electrodes 80U may include one or more work function tuning layer(s) (e.g., n-type work function tuning layer(s) and/or p-type work function tuning layer(s)) formed of material(s) that are suitable for the device type of the upper nanostructure-FETs. Although single-layered gate electrodes 80U are illustrated, the upper gate electrodes 80U may include any number of work function tuning layers, any number of barrier layers, any number of glue layers, and a fill material.

Additionally, a removal process is performed to level top surfaces of the upper gate electrodes 80U and the second ILD 72. The removal process for forming the gate dielectrics 78 may be the same removal process as the removal process for forming the upper gate electrodes 80U. In some embodiments, a planarization process such as a chemical mechanical polish (CMP), an etch-back process, combinations thereof, or the like may be utilized. After the planarization process, the top surfaces of the upper gate electrodes 80U, the gate dielectrics 78, the second ILD 72, and the gate spacers 44 are substantially coplanar (within process variations). Each respective pair of a gate dielectric 78 and a gate electrode 80 (including an upper gate electrode 80U and/or a lower gate electrode 80L) may be collectively referred to as a “gate structure” 90 (including upper gate structures 90U and lower gate structures 90L). Each gate structure 90 extends along three sides (e.g., a top surface, a sidewall, and a bottom surface) of a channel region of a semiconductor nanostructure 26 (see FIG. 1). The lower gate structures 90L may also extend along sidewalls and/or a top surface of a semiconductor fin 20′.

As further illustrated by FIG. 5, gate masks 92 are formed over the gate stacks 42. The formation process may include recessing gate stacks 90, filling the resulting recesses with a dielectric material such as silicon nitride, silicon carbonitride, silicon oxynitride, silicon oxycarbonitride, the like, or a combination thereof, and performing a planarization process to remove the excess portions of the dielectric material over the second ILD 72.

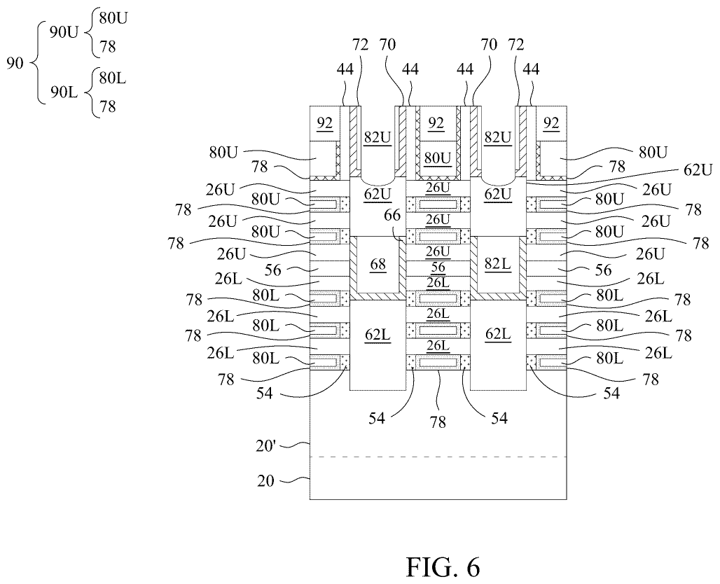

FIGS. 6 through 12 illustrate formation of source/drain contacts 96 (e.g., contact plugs) to electrically couple to the upper epitaxial source/drain regions 62U and/or the lower epitaxial source/drain regions 62L, in accordance with some embodiments. As described in greater detail below, source/drain contact openings 82 are formed to the source/drain regions 62, one or more protective layers 84, 86 are formed over certain surfaces of the structure (e.g., within the source/drain contact openings 82), an epitaxial regrowth process is performed, the one or more protective layers are removed, and the source/drain contact openings 82 are filled with a conductive material 94 to form the source/drain contacts 96.

In FIG. 6, upper source/drain contact openings 82U are formed through the second ILD 72 to the upper epitaxial source/drain regions 62U. For example, upper source/drain contact openings 82U are formed to expose (and optionally extend into) the upper epitaxial source/drain regions 62U. Specifically, the upper source/drain contact openings 82U extend through the second ILD 72 and the second CESL 70 to expose and extend partially into the upper epitaxial source/drain regions 62U. In accordance with some embodiments, photolithography and etching steps may be used to form the upper source/drain contact openings 82U. The etching may be performed by any acceptable etch process, such as a Reactive Ion Etch (RIE), Neutral Beam Etch (NBE), the like, or a combination thereof. The etching may be isotropic or anisotropic.

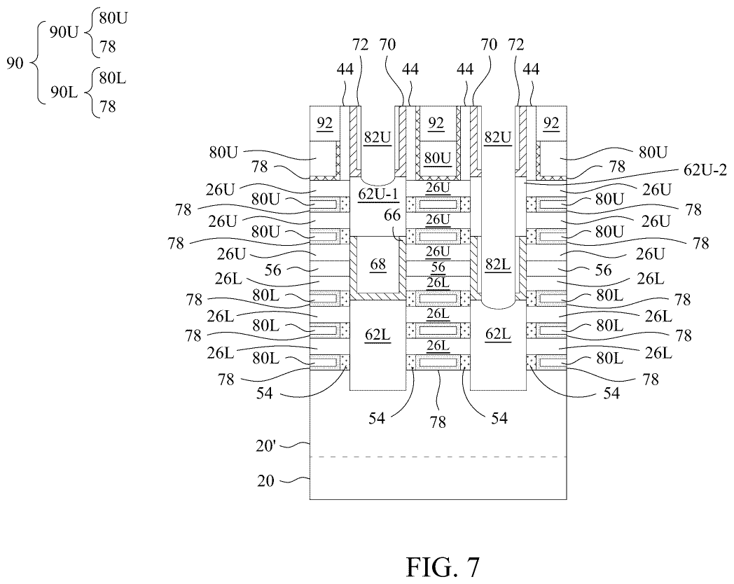

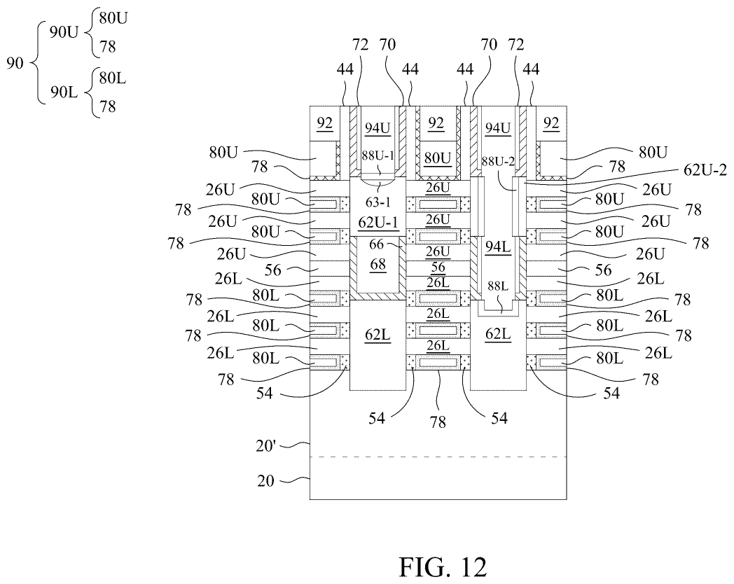

In FIG. 7, lower source/drain contact openings 82L are formed to the lower epitaxial source/drain regions 62L. For example, some of the upper source/drain openings 82U are extended through the corresponding upper epitaxial source/drain regions 62U to expose the underlying lower epitaxial source/drain regions 62L. As such, the upper source/drain contact openings 82U expose upper surfaces of the first upper epitaxial source/drain regions 62U-1, and the lower source/drain contact openings 82L extend through second upper epitaxial source/drain regions 62U-2. Specifically, the lower source/drain contact openings 82L may extend through the second ILD 72, the second CESL 70, the second upper epitaxial source/drain regions 62U-2, the first ILD 68, and/or the first CESL 66 to expose and extend partially into the lower epitaxial source/drain regions 62L. Each of the upper source/drain contact openings 82U may or may not be connected to one of the lower source/drain source/drain contact openings 82L. In areas where the upper and lower source/drain contact openings 82U and 82L are connected, the exposed upper and lower epitaxial source/drain regions 62U-2 and 62L may be electrically connected together by source/drain contacts that are subsequently formed in the connected upper and lower source/drain contact openings 82U and 82L (see FIG. 12).

For example, the upper and lower source/drain contact openings 82U and 82L may be formed by a combination of sequential photolithography and etching processes. In some embodiments, the lower source/drain contact openings 82L may be formed prior to forming the upper source/drain contact openings 82U. Alternatively, this order may be reversed, and the upper source/drain contact openings 82U may be formed prior to forming the lower source/drain contact openings 82L.

In accordance with various embodiments, the source/drain contact openings 82 may have high aspect ratios. For example, the aspect ratios of the lower source/drain contact openings 82L may be up to about 8 to about 15. Nonetheless, after extending the upper source/drain contact openings 82U through the second upper epitaxial source/drain regions 62U-2, the continued extension of the source/drain contact openings 82 (e.g., the lower source/drain contact openings 82L) through the first ILD 68 includes additional lateral etching of the second upper epitaxial source/drain regions 62U-2. In some embodiments, a majority of material of some of the second upper epitaxial source/drain regions 62U-2 is removed during formation of the source/drain contact openings 82. For example, the process may remove as much as between about 50% and about 75% of the corresponding upper epitaxial source/drain regions 62U-2.

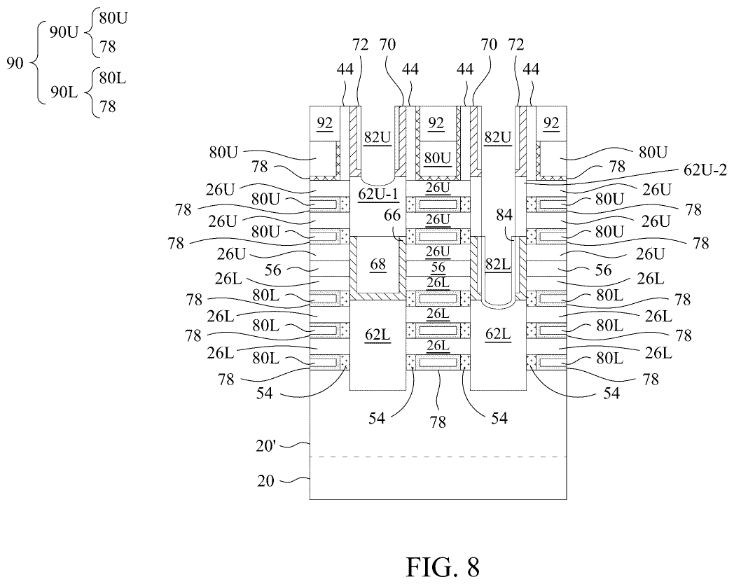

In FIG. 8, a first protective layer 84 is formed in the lower source/drain openings 82L over the lower epitaxial source/drain regions 62L. In some embodiments, the first protective layer 84 may also be formed over some or all of exposed surfaces (e.g., sidewall surfaces) of the first CESL 66 and the first ILD 68. For example, the first protective layer 84 may comprise aluminum oxide and be formed by a deposition process such as CVD, ALD, or the like.

In some embodiments, the first protective layer 84 is conformally deposited over exposed surfaces of the structure including within the lower source/drain contact openings 82L. A sacrificial material (not specifically illustrated) may then be deposited to fill a remainder of the lower source/drain contact openings 82L. The sacrificial material may comprise any suitable dielectric material. A first etch process is then performed on the sacrificial material to remove the sacrificial material entirely from the surfaces of the structure and the upper source/drain contact openings 82U. In particular, the etch process (e.g., an anisotropic etch) may be stopped when the sacrificial material is substantially level with an upper surface of the first ILD 68. A second etch process may then be performed to remove exposed portions of the first protective layer 84. As a result, a remainder of the first protective layer 84 extends along the sidewall surfaces of the first ILD 68 and the first CESL 66 and the upper surfaces of the lower epitaxial source/drain regions 62L. Finally, a third etch process may be performed to remove a remainder of the sacrificial material to expose the remaining portion of the first protective layer 84.

It should be appreciated that any suitable process may be used to form the first protective layer 84 as described. In some embodiments (not specifically illustrated), the remaining portion of the first protective layer 84 may leave some of the sidewall surfaces of the first ILD 68 and/or the first CESL 66 exposed. In other embodiments (not specifically illustrated), the first protective layer 84 may extend along the upper surface of the lower epitaxial source/drain regions 62L while substantially all of the sidewall surfaces of the first ILD 68 and the first CESL 66 remain exposed.

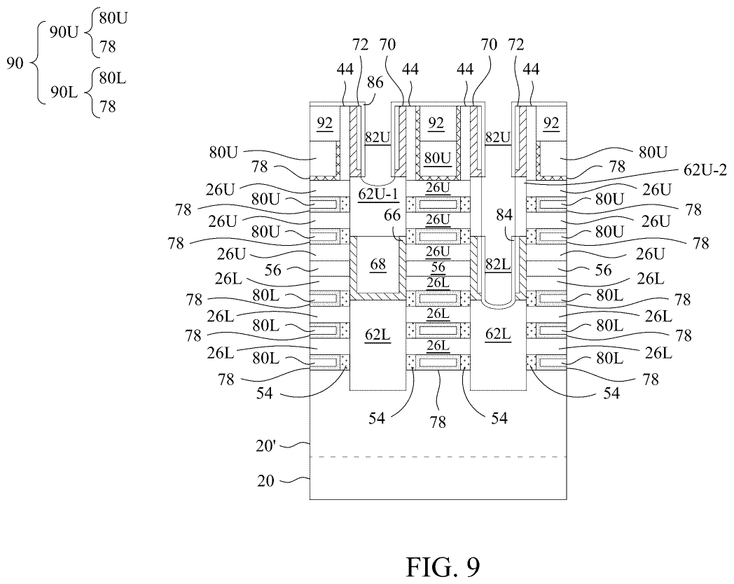

In FIG. 9, a second protective layer 86 is formed over dielectric surfaces in the upper and lower source/drain openings 82U, 82L. In particular, the second protective layer 86 is formed over exposed dielectric surfaces of the second ILD 72, the second CESL 70, the gate spacers 44, and the gate masks 92. In some embodiments (not specifically illustrated), the protective layer 86 may be formed over and along some or all of the sidewall surfaces of the first ILD 68 and the first ILD 66 which may not be covered by the first protective layer 84. As a result, the second protective layer 86 selectively passivates nitride (e.g., Si₃N₄) and oxide (e.g., SiOx) surfaces. In some embodiments (not specifically illustrated), the protective layer 86 may be formed over and along the first protective layer 84.

In accordance with some embodiments, the second protective layer 86 is a self-assembled monolayer (SAM). Formation of the second protective layer 86 includes flowing precursor molecules over the structure to attach to (e.g., physisorb on and/or bond with)-OH groups along the exposed surfaces (e.g., oxide surfaces). For example, the precursor molecules may include a reactive head group and a protective tail group attached to each other through an atom such as silicon or carbon.

In accordance with various embodiments, the precursor molecule comprises an amine (e.g., a silyl amine), a silane (e.g., an alkyl silane), a sulfide (e.g., an alkyl sulfide), or the like. The head group of the precursor molecule may include one, two, or three reactive groups (e.g., leaving groups), wherein one of the reactive groups leaves to provide a point of attachment for the precursor molecule with the dielectric surfaces (e.g., the oxide surface). In embodiments in which the head group includes two or three reactive groups, adjacent attachments of the precursor molecules may bond with one another to form the second protective layer 86 as discrete patches or substantially continuous (e.g., being substantially smooth or a web-like network). In other embodiments (e.g., the head group having any number of reactive groups, such as one reactive group), each adjacent attachment of the precursor molecules may remain discrete from one another to form the second protective layer 86 as discontinuous (e.g., being hair-like).

In some embodiments, the precursor molecule may have a chemical formula of (R₁)ₓ—Si—(R₂)_{[4-x]} for silicon-containing chemicals (e.g., silyl amine or alkyl silane) or CH₃—S—R₂ for sulfur-containing chemicals (e.g., alkyl sulfide), wherein R₁ represents the reactive head group and R₂ represents the protective tail group. For silicon-containing precursor molecules, the head group includes x reactive groups (e.g., leaving groups), which can be one, two, or three, and the tail group includes 4-x non-reactive groups (e.g., protective groups). For sulfur-containing precursor molecules, the head group includes one reactive group, and the tail group includes one non-reactive group. For example, R₁ may be a hydroxy group, an alkoxy group (e.g., methoxy, ethoxy, or the like), an amine group, or a halogen group (e.g., chlorine, fluorine, or the like). In addition, R₂ may be an alkyl group comprising a 1- to 21-carbon chain backbone with or without alkyl side chains (optionally, including isomers thereof) or an aromatic group comprising a phenyl group, a benzyl group, a naphthalene group, an anthracene group, or the like. Some examples of the precursor molecule may include a silyl amine such as (dimethylamino)-trimethylsilane (DMATMS), an alkyl silane such as trimethyl(propyl)silane, or an alkyl sulfide such as diethyl sulfide. However, any suitable chemicals which fit into the above descriptions may be utilized for the precursor molecules.

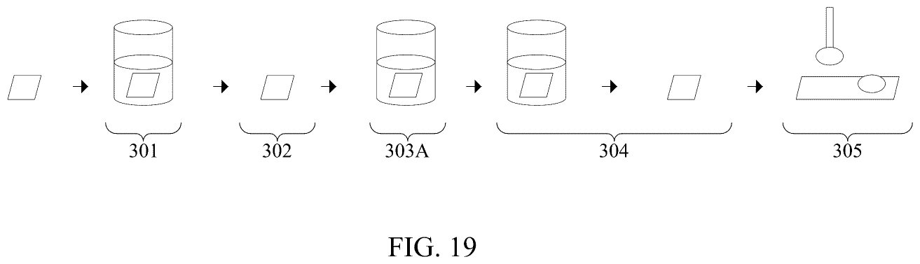

Optionally, as discussed in greater detail below (see FIGS. 19-21), before forming the second protective layer 86, a surface treatment may be performed on the structure to remove native oxides (if any), and/or a surface oxidation treatment may be performed on the dielectric surfaces listed above. For example, the native oxide removal is performed to remove any native oxide layers which may have formed along non-oxide surfaces. In addition, the surface oxidation treatment may convert nitride surfaces (e.g., of the second CESL 70, the gate spacers 44, and/or the gate masks 92) to oxide surfaces. As such, silicon nitride regions of these surfaces may be converted to silicon oxide regions. Further, the surface oxidation treatment may increase concentrations of-OH groups along oxide surfaces (e.g., of the second ILD 68). Note that the surface oxidation treatment may have an analogous effect on a surface of the first protective layer 84 (e.g., an oxide and/or a nitride).

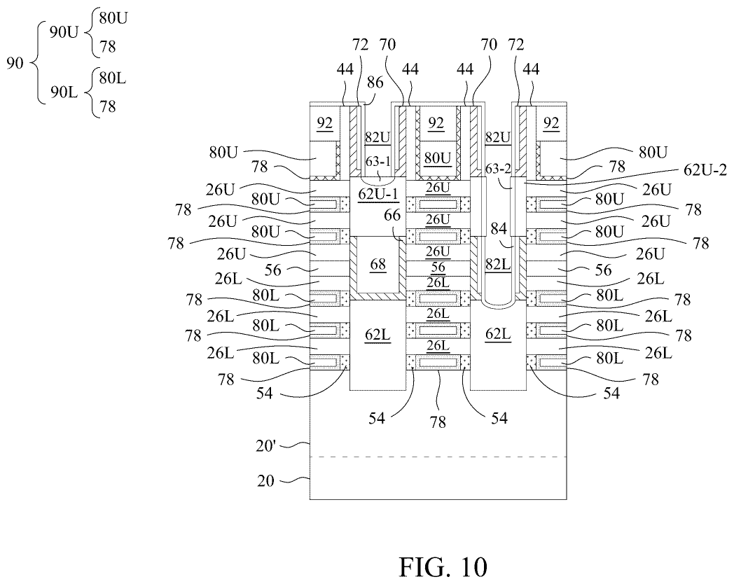

In FIG. 10, a regrowth process is performed on the upper epitaxial source/drain regions 62U to form first epitaxial regrowth layers 63-1 and second epitaxial regrowth layers 63-2. As illustrated, the first epitaxial regrowth layers 63-1 are formed over upper surfaces of the first upper epitaxial source/drain regions 62U-1 which are exposed by the upper source/drain contact openings 82U. In addition, the second epitaxial regrowth layers 63-2 are formed along surfaces of the second upper epitaxial source/drain regions 62U-2.

In accordance with some embodiments, the regrowth process comprises a low temperature epitaxial growth process. In embodiments in which the upper epitaxial source/drain regions 62U comprise n-type epitaxies, the epitaxial regrowth layers 63 may be deposited at temperatures of between 350° C. and 400° C. and may include SiP, SiAs, or a combination thereof. In embodiments in which the upper epitaxial source/drain regions 62U comprise p-type epitaxies, the epitaxial regrowth layers 63 may be deposited at temperatures of between 350° C. and 400° C. and may include SiB, SiGe, SiGeB, or combinations thereof. Deposition temperatures of less than 400° C. serve to reduce the thermal budget while protecting other parts of the stacking transistor structure. In either case, in some embodiments, the epitaxial regrowth layers 63 may have different compositions than the portions of the upper epitaxial source/drain regions 62U that they replaced. In addition, the epitaxial regrowth layers 63 may have different compositions than the immediately adjacent portions of the upper epitaxial source/drain regions 62U (e.g., directly underlying or directly laterally adjacent). For example, the epitaxial regrowth layers 63 may have lower concentrations of the respective impurities (e.g., phosphorous, arsenic, boron, etc.) than these above-described counterparts.

It should be appreciated that the epitaxial regrowth process benefits from being a selective epitaxial growth due to presence of the second protective layer 86. In particular, the low temperature epitaxy of the epitaxial regrowth layers 63 has a high selectivity for semiconductor material (e.g., the material of the upper epitaxial source/drain regions 62U) as compared to the second protective layer 86. Indeed, this selectivity is greater than the relatively low selectivity for semiconductor material as compared to dielectric material (e.g., nitrides such as silicon nitride and oxides such as silicon oxide). As a result, the epitaxial regrowth layers 63 may follow the crystal structures of the underlying upper epitaxial source/drain regions 62U. In addition, little to no amorphous epitaxial material will form over other surfaces of the structure (e.g., including the second protective layer 86).

Moreover, the second protective layer 86 is chemically inert due to the non-reactive tail groups extending outward from the dielectric surfaces. In addition, the second protective layer 86 is thermally stable. These properties further ensure that the epitaxial regrowth process can be performed with higher yield without undesired deposition of the epitaxial material and without undesired side reactions between the second protective layer 86 and other nearby molecules.

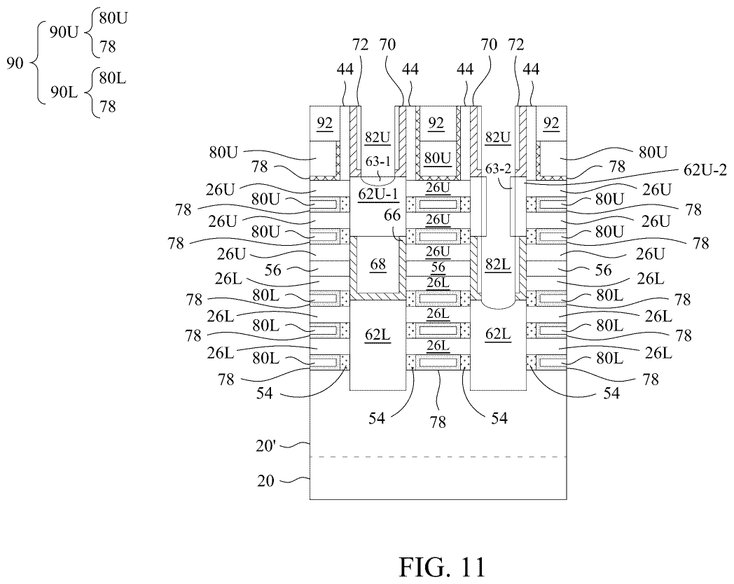

In FIG. 11, the second protective layer 86 and the first protective layer 84 are removed. In various embodiments, the second protective layer 86 may be removed first because the second protective layer 86 may have been formed over the first protective layer 84. The first protective layer 84 may then be removed. For example, the second protective layer 86 may be removed using a chemical dry etch using ammonia and/or hydrogen fluoride. Optionally, a plasma treatment (e.g., a hydrogen radical plasma treatment) may be performed for a thorough cleaning, such as removal of carbon residue (if present). Removal of the first protective layer 84 may be performed using any suitable method, such as an etch process, e.g., used for patterning during the formation of the first protective layer 84 (see FIG. 8).

In FIG. 12, source/drain contacts 96 are formed in the source/drain contact openings 82. In some embodiments, before forming the source/drain contacts 96, metal-semiconductor alloy regions 88 are formed over exposed surfaces of the source/drain regions (e.g., including over the first and second epitaxial regrowth layers 63). The metal-semiconductor alloy regions 88 are formed at interfaces between the source/drain regions 62 and the source/drain contacts 96.

For example, the metal-semiconductor alloy regions 88 can be silicide regions formed of a metal silicide (e.g., nickel silicide (NiSi), titanium silicide (TiSi), tungsten silicide (WSi), molybdenum silicide (MoSi), ruthenium silicide (RuSi), zirconium silicide (ZrSi), antimony silicide (SbSi), cobalt silicide (CoSi), etc.), germanide regions formed of a metal germanide (e.g. nickel germanide (NiGe), titanium germanide (TiGe), tungsten germanide (WGe), molybdenum germanide (MoGe), ruthenium germanide (RuGe), zirconium germanide (ZrGe), antimony germanide (SbGe), cobalt germanide (CoGe), etc.), silicon-germanide regions formed of both a metal silicide and a metal germanide, or the like. The metal-semiconductor alloy regions 88 can be formed before the material(s) of the source/drain contacts 96 by depositing a metal in the openings for the source/drain contacts 96 and then performing a thermal anneal process. The metal can be any metal capable of reacting with the semiconductor materials (e.g., silicon, silicon-germanium, germanium, etc.) of the source/drain regions 62 to form a low-resistance metal-semiconductor alloy, such as nickel, cobalt, titanium, tantalum, platinum, tungsten, other noble metals, other refractory metals, rare earth metals or their alloys.

In addition, the metal can be deposited by a deposition process such as ALD, CVD, PVD, or the like. After the thermal anneal process, a cleaning process, such as a wet clean, may be performed to remove any residual metal from the openings for the source/drain contacts 96, such as from surfaces of the metal-semiconductor alloy regions 88. The metal-semiconductor alloy regions 88 may include upper metal-semiconductor alloy regions 88U along exposed surfaces of the upper source/drain regions 62U and lower metal-semiconductor alloy regions 88L along exposed surfaces of the lower source/drain regions 62L. In some embodiments, portions (which may or may not be entireties) of the first epitaxial regrowth layer 63-1 and the second epitaxial regrowth layer 63-2 are converted to the upper metal-semiconductor alloy regions 88U. For example, in the illustrated cross-section, a portion (but not an entirety) of the first epitaxial regrowth layer 63-1 is converted to the upper metal-semiconductor alloy region 88U-1, while an entirety of the second epitaxial regrowth layer 63-2 is converted to the upper metal-semiconductor alloy region 88U-2. In some embodiments (not specifically illustrated), only portions (e.g., less than entireties) of both the epitaxial regrowth layers 63 are converted to the respective upper metal-semiconductor alloy regions 88U.

Still referring to FIG. 12, a conductive material 94 is formed in the source/drain contact openings 82 and over the metal-semiconductor alloy regions 88 to electrically couple to the upper epitaxial source/drain regions 62U and/or the lower epitaxial source/drain regions 62L. The conductive material 94 may be a metal such as ruthenium, tungsten, molybdenum, cobalt, copper, a copper alloy, silver, gold, aluminum, nickel, combinations thereof, or the like and may be formed by a plating process, PVD, CVD, ALD, or the like. A removal process may be performed to remove excess of the conductive material 94 from the top surfaces of the gate spacers 44 and the second ILD 72. The remaining conductive material 94 forms the source/drain contacts 96 in the source/drain contact openings 82. In some embodiments, a planarization process such as a CMP, an etch-back process, combinations thereof, or the like is utilized. After the planarization process, the top surfaces of the gate spacers 44, the second ILD 72, and the source/drain contacts 96 are substantially coplanar (within process variations). It should be appreciated that an electrical conductivity of the source/drain contacts 96 (e.g., the conductive material) may be greater than an electrical conductivity of the epitaxial source/drain regions 62.

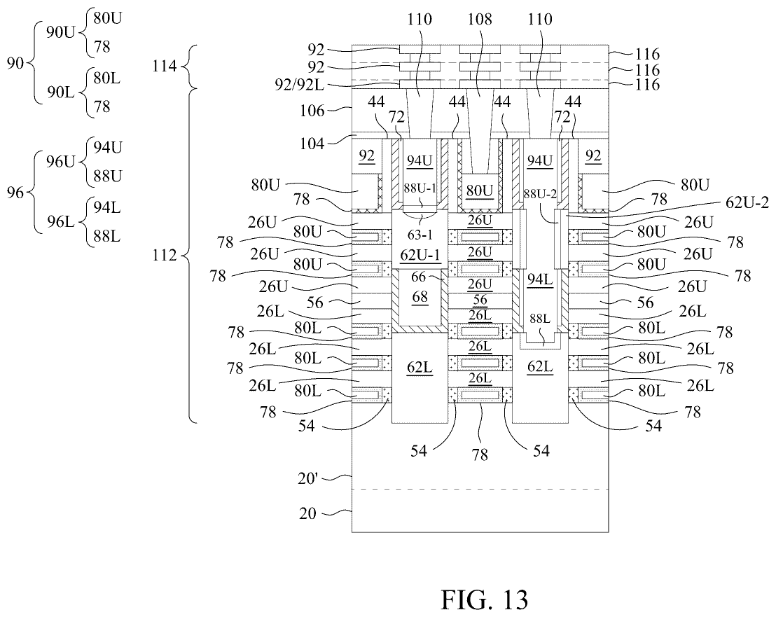

In FIG. 13, an ESL 104 and a third ILD 106 are then formed. In some embodiments, The ESL 104 may include a dielectric material having a high etching selectivity from the etching of the third ILD 106, such as, aluminum oxide, aluminum nitride, silicon oxycarbide, or the like. The third ILD 106 may be formed using flowable CVD, ALD, or the like, and the material may include PSG, BSG, BPSG, USG, or the like, which may be deposited by any suitable method, such as CVD, PECVD, or the like.

Subsequently, gate contacts 108 and source/drain vias 110 are formed to contact the upper gate electrodes 80U and the source/drain contacts 96, respectively. As an example to form the gate contacts 108 and the source/drain vias 110, openings for the gate contacts 108 and the source/drain vias 110 are formed through the third ILD 106 and the ESL 104. The openings may be formed using acceptable photolithography and etching techniques. A liner (not separately illustrated), such as a diffusion barrier layer, an adhesion layer, or the like, and a conductive material are formed in the openings. The liner may include titanium, titanium nitride, tantalum, tantalum nitride, or the like. The conductive material may be cobalt, tungsten, copper, a copper alloy, silver, gold, aluminum, nickel, or the like. A planarization process, such as a CMP, may be performed to remove excess material from the top surface of the third ILD 106. The remaining liner and conductive material form the gate contacts 108 and the source/drain vias 110 in the openings. The gate contacts 108 and the source/drain vias 110 may be formed in distinct processes, or may be formed in the same process. Although shown as being formed in the same cross-section, it should be appreciated that each of the gate contacts 108 and the source/drain vias 110 may be formed in different cross-sections, which may avoid shorting of the contacts.

A front-side interconnect structure 114 is formed on the device layer 112. The front-side interconnect structure 114 includes dielectric layers 116 and layers of conductive features 118 in the dielectric layers 116. The dielectric layers 116 may include low-k dielectric layers formed of low-k dielectric materials. The dielectric layers 116 may further include passivation layers, which are formed of non-low-k and dense dielectric materials such as Undoped Silicate-Glass (USG), silicon oxide, silicon nitride, or the like, or combinations thereof over the low-k dielectric materials. The dielectric layers 116 may also include polymer layers.

The conductive features 118 may include conductive lines and vias, which may be formed using damascene processes. Conductive features 118 may include metal lines and metal vias, which includes diffusion barriers and a copper containing material over the diffusion barriers. There may also be aluminum pads over and electrically connected to the metal lines and vias. In some embodiments, contacts to the lower gate stacks 90L and the lower source/drain regions 62L may be made through a backside of the device layer 112 (e.g., a side opposite to the front-side interconnect structure 114).

Although not specifically illustrated, contacts to the lower gate stacks 90L and the lower epitaxial source/drain regions 62L may be made through a backside of the device layer 122 (e.g., a side opposite to the front-side interconnect structure 128), in accordance with various embodiments. For example, the device layer 122 is between the front-side interconnect structure 128 and a backside interconnect structure. The backside interconnect structure may be substantially similar to the front-side interconnect structure 128 as described above.

Contact vias having contact spacers disposed on sidewalls thereof are formed to extend through at least partially through the device layer 122. The contact vias and the contact spacers may be formed of like materials and like processes as the upper and lower source/drain vias 110. For example, openings may be formed by a combination of photolithography and etching processes. The contact spacers may comprise silicon oxide, silicon nitride, silicon oxynitride, silicon oxycarbonitride, combinations thereof, or the like and may be formed by conformally depositing an insulating material layer (not explicitly illustrated) by CVD, ALD, or the like. Then, lateral portions of the insulating material layer may be etched away by an anisotropic etching process, such as a plasma-based dry etch, thereby forming the contact spacers. Conductive material is then formed in the opening and may include cobalt, tungsten, copper, a copper alloy, silver, gold, aluminum, nickel, or the like. A planarization process, such as a CMP, may be performed to remove excess material from the top surface of the second ILD 72.

In addition, the contact vias and the contact spacers may be formed through the first CESL 66, the first ILD 68, the second CESL 70 and the second ILD 72 prior to forming the ESL 104 and the third ILD 106. The contact vias may be electrically connected to the backside interconnect structure, and the contact vias may also be electrically connected to front-side interconnect structure 128 (e.g., through the upper source/drain contacts 120). In this manner, interconnection between the front-side interconnect structure 128 and the backside interconnect structure may be achieved.

Further, some of the source/drain contacts 96 may be coupled to the contact vias. Formation of the source/drain contacts 96 may be performed similarly as described above in connection with FIGS. 6 through 12. In some embodiments, the third ILD 106 is formed before or as part of formation of the source/drain contacts 96. Moreover, the third ILD 106 may comprise a plurality of layers to facilitate multiple patterning and etching steps in order for the source/drain contacts 96 to be coupled to the contact vias and/or the source/drain regions 62. As such, the third ILD 106 and the ESL 104 may collectively comprise a plurality of ESLs and ILD layers.

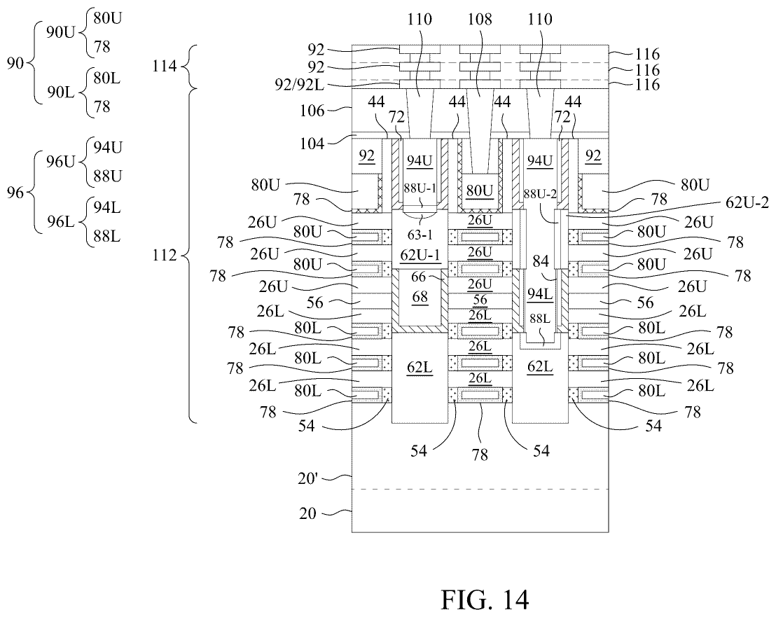

FIGS. 14-16 illustrate additional embodiments for forming stacking transistors with some variations to the stacking transistors described above. Note that the processes and features for the stacking transistors described below may be the same or analogous to the processes and features described above unless otherwise specified.

FIG. 14 illustrates embodiments in which the step described above in connection with FIG. 11 includes removing the second protective layer 86, wherein some or all of the first protective layer 84 remains in the lower source/drain contact openings 82L. Optionally, before forming the lower metal-semiconductor alloy regions 88L, an etch process may be performed to remove portions of the first protective layer 84 from the upper surface of the lower epitaxial source/drain region 62L. Remaining portions of the first protective layer 84 along sidewalls of the first ILD 68 and the CESL 66 may be thinner than as deposited (see FIG. 8). As illustrated, the source/drain contacts 96 may then be formed with formation of the metal-semiconductor alloy regions 88 and the conductive material 94, similarly as described above.

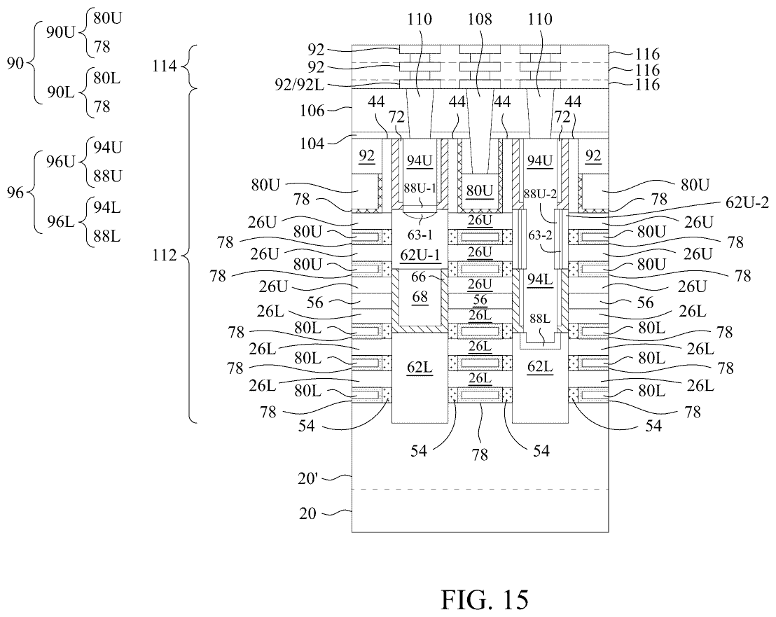

FIG. 15 illustrates embodiments in which the step described above in connection with FIG. 12 includes at least some of the second epitaxial regrowth layers 63-2 remaining after formation of the upper metal-semiconductor alloy regions 88U-2. Some of the second epitaxial regrowth layers 63-2 may be converted to the upper metal-semiconductor alloy regions 88U-2 while remaining portions of the second epitaxial regrowth layers 63-2 along sidewalls of the upper epitaxial source/drain regions 62U-2 may be thinner than as formed (see FIG. 10). As illustrated, the source/drain contacts 96 may then be completed with formation of the conductive fill material 94, similarly as described above.

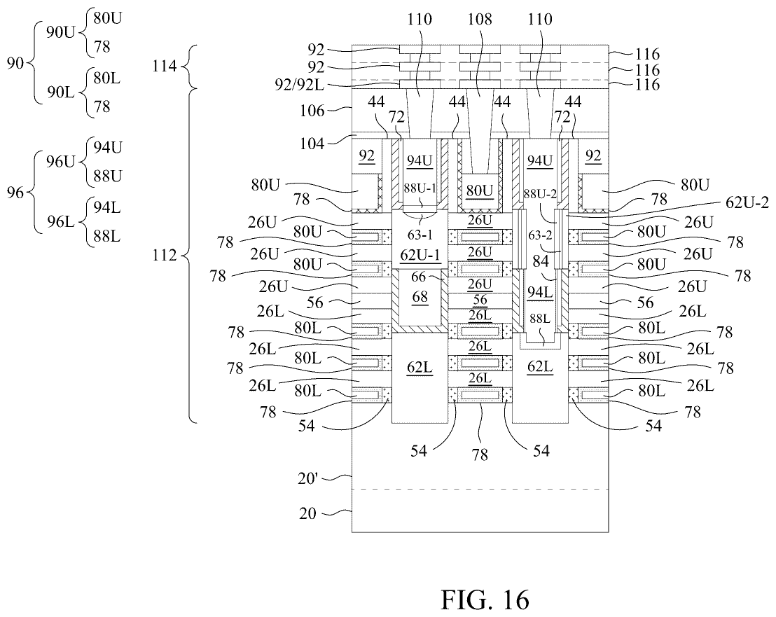

FIG. 16 illustrates embodiments in which at least some of the first protective layer 84 remains after removal of the second protective layer 86 (see FIGS. 11 and 14) and at least some of the second epitaxial regrowth layer 63-2 remains after formation of the upper metal-semiconductor alloy regions 88U-2 (see FIGS. 12 and 15). For example, FIG. 16 represents a combination of features described above in connection with FIGS. 14 and 15. Similarly, the source/drain contacts 96 may then be completed with formation of the conductive fill material 94, similarly as described above.

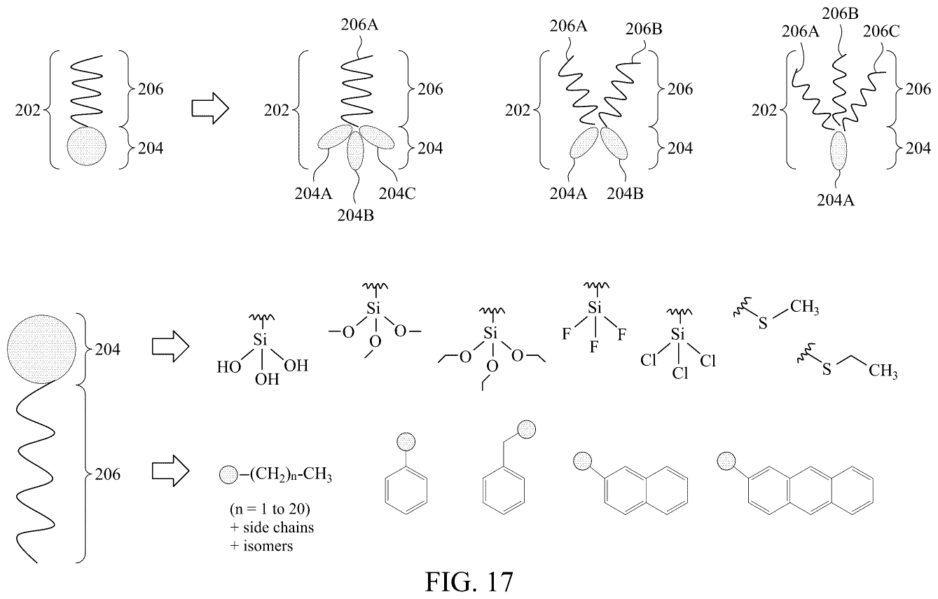

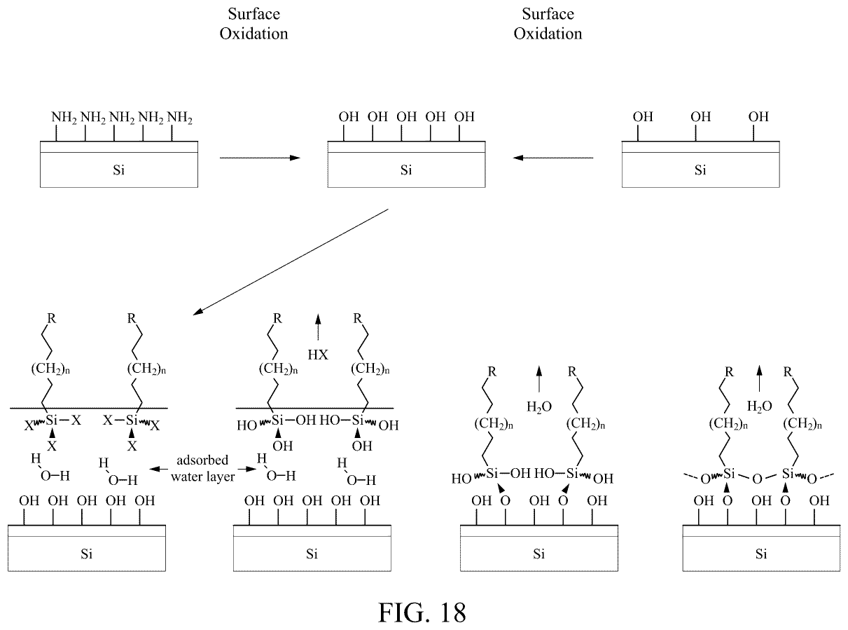

FIGS. 17 and 18 illustrate chemical structures and reaction mechanisms in the formation of the second protective layer 86. FIG. 17 illustrates general structures of the precursor molecule, and FIG. 18 illustrates an exemplary chemical reaction mechanism for the surface treatment and formation of the second protective layer 86.

FIG. 17 depicts the precursor molecule 202 with the head group 204 and the tail group 206. As discussed above, and as illustrated along the top row, the head group 204 may comprise of one or more (e.g., up to three) reactive groups 204A, 204B, 204C (e.g., leaving groups), and the tail group 206 may comprise one or more (e.g., up to three) non-reactive groups 206A, 206B, 206C (e.g., protective groups). Note that any suitable combinations thereof may be utilized, such as a head group 204 with one reactive group and a tail group 206 with one non-reactive group 206A.

Further illustrated along the bottom rows are some exemplary head groups 204 (and corresponding reactive groups) and some exemplary tail groups 206 (and corresponding non-reactive groups). For example, the head group 204 may comprise a silane of hydroxy groups, methoxy groups, ethoxy groups, halogens (e.g., fluorine, chlorine, iodine), or the like or an alkyl sulfide such as methyl sulfide, ethyl sulfide, or the like. Note that the silicon atom may be considered part of the head group 204, wherein each of the attached functional groups is a reactive group 204A, 204B, 204C. In addition, the tail group 206 may comprise a 1- to 21-carbon chain backbone (e.g., including a 20-carbon chain backbone) with or without alkyl side chains (optionally, including isomers thereof) or an aromatic group such as a phenyl group, a benzyl group, a naphthalene group, an anthracene group, or the like. Note that each of the alkyl side chains may or may not include branching and may be any suitable length, such as methyl, ethyl, propyl, butyl, or the like.

FIG. 18 shows the surface treatment (e.g., the surface oxidation treatment) of an exemplary nitride layer (e.g., the second CESL 70) and an exemplary oxide layer (e.g., the second ILD 72) as well as reaction of the precursor molecules with the treated surfaces to form the second protective layer 86. The surface oxidation treatment may include a rinse comprising deionized water, ozone, hydrogen peroxide, or combinations thereof. In some embodiments, a first rinse includes ozone and/or hydrogen peroxide, and a second rinse includes deionized water. After the surface treatment, the precursor molecule is applied to the structure using a suitable method, such as the exemplary methods described below in connection with FIGS. 19-21.

As illustrated, the surface treatment may convert —NH₂ groups along nitride surfaces (e.g., Si₃N₄) into-OH groups. In addition, the surface treatment may increase the surface concentration (e.g., surface density) of —OH groups along oxide surfaces (e.g., SiOx). Upon application of the precursor molecule, the precursor molecules will physisorb along the-OH surfaces. In addition, the precursor molecules may undergo hydrolysis reactions with water molecules in the ambient or along the —OH surfaces. The hydrolysis reactions result in-OH head groups replacing some of the reactive groups of the head groups. Further, the precursor molecules (e.g., some of which having been hydrolyzed) will bond to the dielectric surfaces through a mechanism such as covalent grafting. Finally, in some embodiments, some of the head groups (e.g., original reactive groups or new-OH head groups) of adjacent covalently bonded precursor molecules may react with one another to bond the precursor molecules to one another. This mechanism may also be referred to as in-plane reticulation. As discussed above, the in-place reticulation may result in the second protective layer 86 comprising discrete patches, a web-like network, a smooth contour, or combinations thereof.

FIGS. 19 through 21 illustrate exemplary methods for forming the second protective layer 86 (see FIG. 9). Each of the exemplary methods includes same surface treatment steps (e.g., native oxide removal and surface oxidation treatment), distinct SAM treatment steps to form the second protective layer 86, and same post-processing steps (e.g., rinsing and observation). In a first step 301, dilute hydrogen fluoride (e.g., 1:100 dHF) is applied to the structure (e.g., at wafer level) using a suitable method such as immersing the structure in the dHF for up to about 1 minute. In a second step 302, the structure is rinsed with deionized water (DIW) and dried by blowing nitrogen gas (N₂) thereover. In a third step 303, a SAM treatment is performed to form the second protective layer 86. In a fourth step 304, the structure may be rinsed with an alcohol such as isopropyl alcohol, rinsed with deionized water, and dried by blowing nitrogen gas thereover. In a fifth step 305, a SAM coverage observation may be performed to confirm sufficient coverage of the second protective layer 86. The SAM coverage observation may include measuring the contact angles of several drops of water (e.g., with about 5 spots on various locations on the wafer) or analyzing the coefficient of friction change using a tribometer.

FIG. 19 illustrates formation of the second protective layer 86 using a first SAM treatment process 303A by immersing the structure into a SAM solution containing the precursor molecule. For example, the SAM solution includes the precursor molecule dissolved in an alcohol or acetate solvent, such as methanol, ethanol, isopropyl alcohol, propylene glycol methyl ether acetate (PGMEA), or the like. The first SAM treatment process includes immersing the wafer into a container or vat of the SAM solution at temperatures ranging from 5° C. to 60° C., at an ambient pressure, and for 1 minute to 5 minutes for the precursor molecules to react and form the second protective layer 86 over the structure.

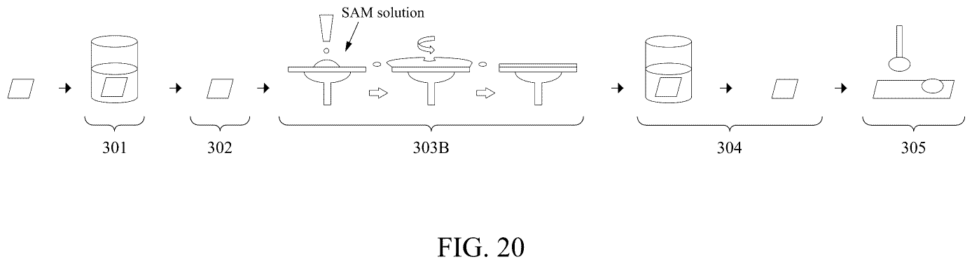

FIG. 20 illustrates formation of the second protective layer 86 using a second SAM treatment process 303B by spin-coating the structure with the SAM solution. For example, the SAM solution may be as described above in connection with the first SAM treatment process. The second SAM treatment process includes depositing 5 mL to 20 mL of the SAM solution over the wafer which is secured to a spinning platform, spinning the wafer at a spin rate of 50 rpm to 300 rpm for 5 seconds to 30 seconds to fully spread and coat the SAM solution over the wafer, and allowing the precursor molecules to react and form the second protective layer 86 at temperatures ranging from 5° C. to 60° C., at an ambient pressure, and for 1 minute to 5 minutes.

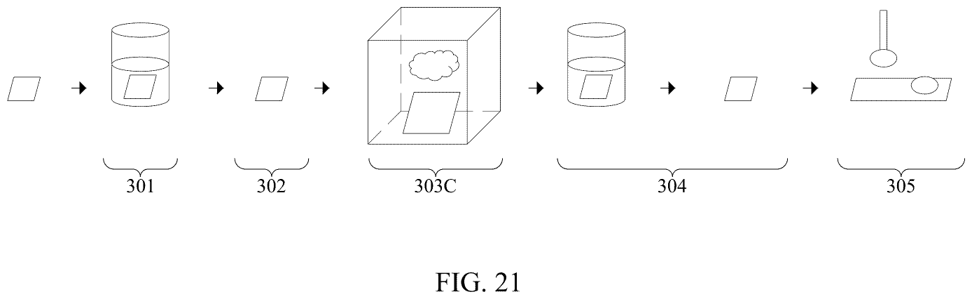

FIG. 21 illustrates formation of the second protective layer 86 using a third SAM treatment process 303C by flowing the precursor molecules (as discussed above) over the structure in a deposition chamber. For example, the precursor molecules are flowed over the wafer at temperatures ranging from 50° C. to 300° C., at pressures ranging from 5 torr to 300 torr, and for 1 minute to 5 minutes for the precursor molecules to react and form the second protective layer 86 over the structure.

Various advantages are achieved. For example, after forming the lower source/drain contact openings 82L to the lower epitaxial source/drain regions 62L, an epitaxial regrowth process may be performed on the upper epitaxial source/drain regions 62U. The upper epitaxial source/drain regions 62U which were etched through to form the lower source/drain contact openings 82L may have lost a majority of their epitaxial material in the process. As such, those upper epitaxial source/drain regions 62U may particularly benefit from the epitaxial regrowth process to replenish substantial amounts of the epitaxial material. The steps of forming one or more protective layers over the dielectric surfaces and the lower epitaxial source/drain regions 62L ensures that the epitaxial regrowth process is selective to the upper epitaxial source/drain regions 62U. In particular, the second protective layer 86 may be selectively formed over certain dielectric surfaces, and the epitaxial regrowth layers 63 may then be selectively formed over the upper epitaxial source/drain regions 62U. The resulting stacking transistors (as well as the semiconductor devices which utilize these transistors) may be manufactured at higher yields and operate with improved performance and reliability.

In an embodiment, a method includes forming an upper gate structure adjacent to a first source/drain region and a second source/drain region and a lower gate structure adjacent to a third source/drain region; patterning a first opening and a second opening through a first dielectric layer to expose the first source/drain region and the second source/drain region; patterning to extend the second opening through a second dielectric layer to expose the third source/drain region; forming a protective layer over exposed surfaces of the first dielectric layer; forming a first epitaxial regrowth layer over the first source/drain region and a second epitaxial regrowth layer over the second source/drain region; removing the protective layer; forming a first source/drain contact to the first epitaxial regrowth layer; and forming a second source/drain contact to the second epitaxial regrowth layer and the third source/drain region. In another embodiment, forming the first epitaxial regrowth layer is performed simultaneously with forming the second epitaxial regrowth layer. In another embodiment, forming the first epitaxial regrowth layer and the second epitaxial regrowth layer comprises an epitaxial process at a temperature of less than about 400° C. In another embodiment, forming the protective layer comprises flowing a precursor molecule over the exposed surfaces of the first dielectric layer, and wherein the precursor molecule comprises a silyl amine, an alkyl silane, or an alkyl sulfide. In another embodiment, removing the protective layer comprises a chemical dry etch process, and wherein an etchant of the chemical dry etch process comprises at least one of ammonia or hydrogen fluoride. In another embodiment, removing the protective layer further comprises performing a hydrogen plasma treatment. In another embodiment, the method further includes, before forming the protective layer, forming an aluminum oxide layer over the third source/drain region and the second dielectric layer. In another embodiment, the protective layer is chemically bonded to the aluminum oxide layer.

In an embodiment, a method includes forming an opening through a first plurality of dielectric layers to expose a first source/drain region; extending the opening through a second plurality of dielectric layers to expose a second source/drain region; forming a first protective layer along exposed surfaces of the second plurality of dielectric layers and the second source/drain region; forming a second protective layer along exposed surfaces of the first plurality of dielectric layers; forming an epitaxial regrowth layer on the first source/drain region; removing the second protective layer; removing the first protective layer; and forming a source/drain contact in the opening, the source/drain contact being coupled to the first source/drain region and to the second source/drain region. In another embodiment, extending the opening through the second plurality of dielectric layers comprises extending the opening through the first source/drain region. In another embodiment, the first protective layer comprises aluminum oxide. In another embodiment, forming the second protective layer comprises a precursor molecule reacting with and attaching to the first plurality of dielectric layers, and wherein the precursor molecule comprises at least one of alkyl groups or aromatic groups. In another embodiment, forming the second protective layer comprises performing an immersion in a solution comprising the precursor molecule dissolved in a solvent. In another embodiment, forming the second protective layer comprises spin-coating the precursor molecule over the first plurality of dielectric layers. In another embodiment, forming the second protective layer comprises flowing the precursor molecule over the first plurality of dielectric layers in a deposition chamber.

In an embodiment, a semiconductor device includes a first epitaxial region, the first epitaxial region comprising a first epitaxial material; a first silicide region on the first epitaxial region; first nanostructures adjacent to the first epitaxial region; a second epitaxial region overlapping the first epitaxial region, the second epitaxial region comprising a second epitaxial material being different from the first epitaxial material; a second silicide region on the second epitaxial region; an interlayer dielectric layer disposed over the first epitaxial region and below the second epitaxial region; a contact plug extending through the second epitaxial region and the interlayer dielectric layer to electrically couple to the first epitaxial region, wherein an electrical conductivity of the contact plug is greater than an electrical conductivity of the first epitaxial region; a third epitaxial region laterally adjacent to the second epitaxial region, the third epitaxial region comprising the second epitaxial material and a third epitaxial material, the third epitaxial material being different from the first epitaxial material and the second epitaxial material; a third silicide region on the third epitaxial region, the third silicide region being in contact with the third epitaxial material of the third epitaxial region; second nanostructures extending from the second epitaxial region to the third epitaxial region; a first gate structure around the first nanostructures; and a second gate structure overlapping the first gate structure and around the second nanostructures. In another embodiment, the second epitaxial region comprises the third epitaxial material, and wherein the second silicide region is in contact with the third epitaxial material of the second epitaxial region. In another embodiment, the semiconductor device further includes a metal oxide layer extending from the first silicide region to the second silicide region. In another embodiment, the metal oxide layer comprises aluminum oxide. In another embodiment, the second epitaxial region is free of the third epitaxial material.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method comprising:
forming an upper gate structure adjacent to a first source/drain region and a second source/drain region and a lower gate structure adjacent to a third source/drain region;
patterning a first opening and a second opening through a first dielectric layer to expose the first source/drain region and the second source/drain region;
patterning to extend the second opening through a second dielectric layer to expose the third source/drain region;
forming a protective layer over exposed surfaces of the first dielectric layer;
forming a first epitaxial regrowth layer over the first source/drain region and a second epitaxial regrowth layer over the second source/drain region;
removing the protective layer;
forming a first source/drain contact to the first epitaxial regrowth layer; and
forming a second source/drain contact to the second epitaxial regrowth layer and the third source/drain region.

2. The method of claim 1, wherein forming the first epitaxial regrowth layer is performed simultaneously with forming the second epitaxial regrowth layer.

3. The method of claim 1, wherein forming the first epitaxial regrowth layer and the second epitaxial regrowth layer comprises an epitaxial process at a temperature of less than about 400° C.

4. The method of claim 1, wherein forming the protective layer comprises flowing a precursor molecule over the exposed surfaces of the first dielectric layer, and wherein the precursor molecule comprises a silyl amine, an alkyl silane, or an alkyl sulfide.

5. The method of claim 1, wherein removing the protective layer comprises a chemical dry etch process, and wherein an etchant of the chemical dry etch process comprises at least one of ammonia or hydrogen fluoride.

6. The method of claim 5, wherein removing the protective layer further comprises performing a hydrogen plasma treatment.

7. The method of claim 1, further comprising, before forming the protective layer, forming an aluminum oxide layer over the third source/drain region and the second dielectric layer.

8. The method of claim 7, wherein the protective layer is chemically bonded to the aluminum oxide layer.

9. A method comprising:
forming an opening through a first plurality of dielectric layers to expose a first source/drain region;
extending the opening through a second plurality of dielectric layers to expose a second source/drain region;
forming a first protective layer along exposed surfaces of the second plurality of dielectric layers and the second source/drain region;
forming a second protective layer along exposed surfaces of the first plurality of dielectric layers;
forming an epitaxial regrowth layer on the first source/drain region;
removing the second protective layer;
removing the first protective layer; and
forming a source/drain contact in the opening, the source/drain contact being coupled to the first source/drain region and to the second source/drain region.

10. The method of claim 9, wherein extending the opening through the second plurality of dielectric layers comprises extending the opening through the first source/drain region.

11. The method of claim 9, wherein the first protective layer comprises aluminum oxide.

12. The method of claim 9, wherein forming the second protective layer comprises a precursor molecule reacting with and attaching to the first plurality of dielectric layers, and wherein the precursor molecule comprises at least one of alkyl groups or aromatic groups.

13. The method of claim 12, wherein forming the second protective layer comprises performing an immersion in a solution comprising the precursor molecule dissolved in a solvent.

14. The method of claim 12, wherein forming the second protective layer comprises spin-coating the precursor molecule over the first plurality of dielectric layers.

15. The method of claim 12, wherein forming the second protective layer comprises flowing the precursor molecule over the first plurality of dielectric layers in a deposition chamber.

16. A semiconductor device comprising:
a first epitaxial region, the first epitaxial region comprising a first epitaxial material;
a first silicide region on the first epitaxial region;
first nanostructures adjacent to the first epitaxial region;
a second epitaxial region overlapping the first epitaxial region, the second epitaxial region comprising a second epitaxial material being different from the first epitaxial material;
a second silicide region on the second epitaxial region;
an interlayer dielectric layer disposed over the first epitaxial region and below the second epitaxial region;
a contact plug extending through the second epitaxial region and the interlayer dielectric layer to electrically couple to the first epitaxial region, wherein an electrical conductivity of the contact plug is greater than an electrical conductivity of the first epitaxial region;
a third epitaxial region laterally adjacent to the second epitaxial region, the third epitaxial region comprising the second epitaxial material and a third epitaxial material, the third epitaxial material being different from the first epitaxial material and the second epitaxial material;
a third silicide region on the third epitaxial region, the third silicide region being in contact with the third epitaxial material of the third epitaxial region;
second nanostructures extending from the second epitaxial region to the third epitaxial region;
a first gate structure around the first nanostructures; and
a second gate structure overlapping the first gate structure and around the second nanostructures.

17. The semiconductor device of claim 16, wherein the second epitaxial region comprises the third epitaxial material, and wherein the second silicide region is in contact with the third epitaxial material of the second epitaxial region.

18. The semiconductor device of claim 16, further comprising a metal oxide layer extending from the first silicide region to the second silicide region.

19. The semiconductor device of claim 18, wherein the metal oxide layer comprises aluminum oxide.

20. The semiconductor device of claim 16, wherein the second epitaxial region is free of the third epitaxial material.
